(19) United States
(12) Patent Application Publication
(10) Pub. No.: US 2025/0015777 A1
(43) Pub. Date: Jan. 9, 2025

(54) ACOUSTIC WAVE DEVICE AND FILTER DEVICE

(71) Applicant: Murata Manufacturing Co., Ltd., Nagaokakyo-shi (JP)

(72) Inventors: Katsuhito KURODA, Nagaokakyo-shi (JP); Masashi OMURA, Nagaokakyo-shi (JP); Hirotsugu MORI, Nagaokakyo-shi (JP)

(21) Appl. No.: 18/888,322

(22) Filed: Sep. 18, 2024

Related U.S. Application Data
(63) Continuation of application No. PCT/JP2023/010379, filed on Mar. 16, 2023.

(30) Foreign Application Priority Data
Jun. 10, 2022 (JP) 2022-094484

(51) Int. Cl. H03H 9/02; H03H 9/05; H03H 9/10; H03H 9/13; H03H 9/17; H03H 9/56

(52) U.S. Cl. CPC H03H 9/02133; H03H 9/02102; H03H 9/0523; H03H 9/105; H03H 9/131; H03H 9/132; H03H 9/173; H03H 9/175; H03H 9/176; H03H 9/562; H03H 9/564; H03H 9/568

(57) ABSTRACT

An acoustic wave device includes a piezoelectric layer including first and second major surfaces, first and second excitation electrodes respectively on the first and second major surfaces, first and second wiring electrodes respectively coupled to the first and second excitation electrodes, and an insulating layer on the second major surface and covering at least a portion of the second excitation electrode and the second wiring electrode. The piezoelectric layer is sandwiched between the first and second excitation electrodes. A region in the piezoelectric layer sandwiched between the first and second excitation electrodes defines an excitation region. An acoustic reflector is provided within the insulating layer and overlaps the excitation region. The first and second wiring electrodes do not overlap the acoustic reflector. Material arrangements of the first and second excitation electrodes are the same, and material arrangements of the first and second wiring electrodes are the same.

### CROSS REFERENCE TO RELATED APPLICATIONS

This application claims the benefit of priority to Japanese Patent Application No. 2022-094484 filed on Jun. 10, 2022 and is a Continuation Application of PCT Application No. PCT/JP2023/010379 filed on Mar. 16, 2023. The entire contents of each application are hereby incorporated herein by reference.

### BACKGROUND OF THE INVENTION

### 1. Field of the Invention

The present invention relates to acoustic wave devices and filter devices.

### 2. Description of the Related Art

Acoustic wave devices have been widely used, for example, in filters for mobile phones. Japanese Unexamined Patent Application Publication No. 2020-141337 discloses an example of a piezoelectric thin-film resonator as an acoustic wave device. In this piezoelectric thin-film resonator, a piezoelectric film is provided on a substrate. Electrodes provided on respective major surfaces of the piezoelectric film face each other. The region where the electrodes face each other is referred to as a resonance region. Each of the electrodes includes a portion extended from the resonance region. This portion is used as a portion coupled to another piezoelectric thin-film resonator. The substrate includes a void. The resonance region faces the void.

In each electrode of the piezoelectric thin-film resonator described in Japanese Unexamined Patent Application Publication No. 2020-141337, the portion coupled to the other piezoelectric thin-film resonator is configured in the same manner as the portion positioned in the resonance region. It is therefore difficult to sufficiently lower the wiring resistance. Furthermore, in the electrode, the portion facing the void in the substrate is configured in the same manner as the portion not facing the void. Therefore, the difference between stresses in the portion facing the void and the portion not facing the void tends to be large. In this case, large stress is applied to the piezoelectric thin-film resonator as a whole. Accordingly, it may be difficult for the piezoelectric thin-film resonator to possess desired electrical characteristics or the piezoelectric thin-film resonator may be damaged.

### SUMMARY OF THE INVENTION

Example embodiments of the present invention provide acoustic wave devices and filter devices in each of which a wiring resistance is lowered and a stress applied thereto is able to be reduced or prevented.

An acoustic wave device according to an example embodiment of the present invention includes a piezoelectric layer including a first major surface and a second major surface opposed to each other, a first excitation electrode on the first major surface of the piezoelectric layer and a second excitation electrode on the second major surface, a first wiring electrode coupled to the first excitation electrode and a second wiring electrode coupled to the second excitation electrode, and an insulating layer on the second major surface of the piezoelectric layer and covering at least a portion of the second excitation electrode and the second wiring electrode, in which the first excitation electrode and the second excitation electrode oppose each other with the piezoelectric layer sandwiched therebetween, a region in the piezoelectric layer sandwiched between the first excitation electrode and the second excitation electrode is an excitation region, an acoustic reflector is provided within the insulating layer and overlaps at least a portion of the excitation region in plan view, neither the first wiring electrode nor the second wiring electrode overlaps the acoustic reflector in plan view, and a layer structure of the first excitation electrode has a same arrangement of a material from a piezoelectric layer side, as a layer structure of the second excitation electrode, and a layer structure of the first wiring electrode has the same arrangement of a material from the piezoelectric layer side, as a layer structure of the second wiring electrode.

A filter device according to an example embodiment of the present invention includes a serial arm resonator, and a parallel arm resonator, in which at least one of the serial arm resonator and the parallel arm resonator is defined by a acoustic wave device according to an example embodiment of the present invention.

With the acoustic wave devices and the filter devices according to example embodiments the present invention, a wiring resistance reduced, and a stress applied thereto is able to be reduced or prevented.

The above and other elements, features, steps, characteristics and advantages of the present invention will become more apparent from the following detailed description of the example embodiments with reference to the attached drawings.

### BRIEF DESCRIPTION OF THE DRAWINGS

FIG. 1 is a schematic elevational cross-sectional view of an acoustic wave device according to a first example embodiment of the present invention.

FIG. 2 is a schematic plan view of the acoustic wave device according to the first example embodiment of the present invention.

FIG. 3 is a schematic elevational cross-sectional view for explaining a symmetric structure in the first example embodiment of the present invention.

FIG. 4 is a schematic plan view for explaining another symmetric structure in the first example embodiment of the present invention.

FIG. 5 is a schematic elevational cross-sectional view of an acoustic wave device according to a first modification of the first example embodiment of the present invention.

FIG. 6 is a schematic elevational cross-sectional view of an acoustic wave device according to a second modification of the first example embodiment of the present invention.

FIG. 7 is a schematic elevational cross-sectional view of an acoustic wave device according to a second example embodiment of the present invention.

FIG. 8 is a schematic elevational cross-sectional view of an acoustic wave device according to a third example embodiment of the present invention.

FIG. 9 is a schematic elevational cross-sectional view of an acoustic wave device according to a fourth example embodiment of the present invention.

FIG. 10 is a schematic elevational cross-sectional view of an acoustic wave device according to a first modification of the fourth example embodiment of the present invention.

FIG. 11 is a schematic elevational cross-sectional view of an acoustic wave device according to a second modification of the fourth example embodiment of the present invention.

FIG. 12 is a schematic elevational cross-sectional view of an acoustic wave device according to a third modification of the fourth example embodiment of the present invention.

FIG. 13 is a schematic elevational cross-sectional view of an acoustic wave device according to a fourth modification of the fourth example embodiment of the present invention.

FIG. 14 is a schematic elevational cross-sectional view of an acoustic wave device according to a fifth example embodiment of the present invention.

FIG. 15 is a schematic plan view of an electrode structure on a piezoelectric layer in a modification of the fifth example embodiment of the present invention.

FIG. 16 is a schematic elevational cross-sectional view of an acoustic wave device according to a sixth example embodiment of the present invention.

FIG. 17 is a circuit diagram of a filter device according to a seventh example embodiment of the present invention.

FIG. 18 is schematic elevational cross-sectional views of a serial arm resonator and a parallel arm resonator in the seventh example embodiment of the present invention.

### DETAILED DESCRIPTION OF THE EXAMPLE EMBODIMENTS

Hereinafter, the present invention is clarified by describing specific example embodiments of the present invention with reference to the drawings.

Each example embodiment described in the specification is illustrative, and configurations of different example embodiments can be partially substituted for each other or can be partially combined.

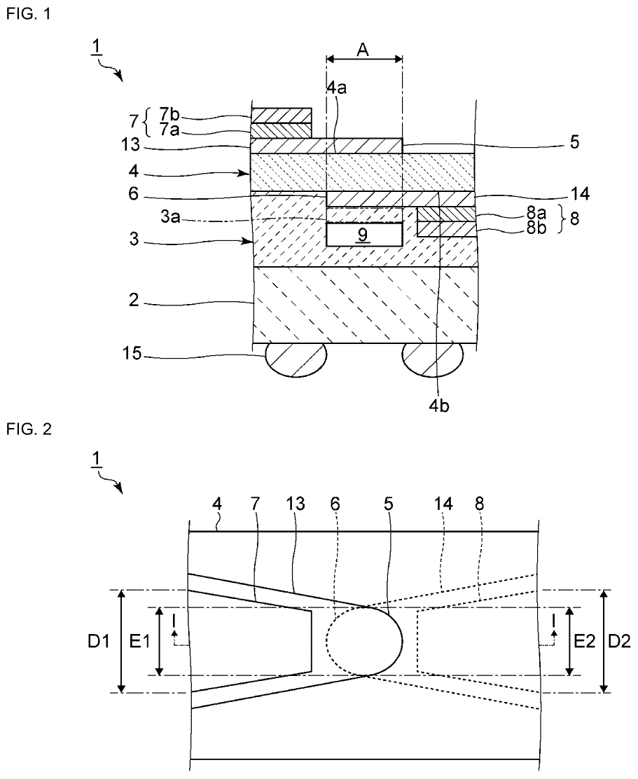

FIG. 1 is a schematic elevational cross-sectional view of an acoustic wave device according to a first example embodiment of the present invention.

An acoustic wave device 1 of the first example embodiment is, for example, a bulk acoustic wave (BAW) element. The acoustic wave device 1 includes a support substrate 2, an insulating layer 3, a piezoelectric layer 4, a first excitation electrode 5, a second excitation electrode 6, a first wiring electrode 7, and a second wiring electrode 8. The insulating layer 3 is provided on the support substrate 2. On the insulating layer 3, the piezoelectric layer 4 is provided. That is, the piezoelectric layer 4 is indirectly provided on the support substrate 2 with the insulating layer 3 interposed therebetween.

The support substrate 2 can be made of a semiconductor, such as silicon, ceramics such as aluminum oxide, or the like, for example. The insulating layer 3 can be made of a proper dielectric, such as silicon oxide or tantalum pentoxide, for example. The piezoelectric layer 4 can be made of lithium niobate, lithium tantalate, zinc oxide, aluminum nitride, crystal, lead zirconate titanate (PZT), or the like, for example. Preferably, the piezoelectric layer 4 is made of, for example, lithium tantalate, lithium niobate, aluminum nitride, or the like.

The piezoelectric layer 4 includes a first major surface 4a and a second major surface 4b. The first major surface 4a and the second major surface 4b oppose each other. The second major surface 4b is positioned closer to the insulating layer 3, between the first major surface 4a and the second major surface 4b.

The first excitation electrode 5 is provided on the first major surface 4a. The second excitation electrode 6 is provided on the second major surface 4b. The first excitation electrode 5 and the second excitation electrode 6 face each other with the piezoelectric layer 4 sandwiched therebetween. The region in the piezoelectric layer 4 sandwiched between the first excitation electrode 5 and the second excitation electrode 6 is referred to as an excitation region A. When an alternating-current electric field is applied between the first excitation electrode 5 and the second excitation electrode 6, acoustic waves are excited in the excitation region A.

In the first example embodiment, the first excitation electrode 5 and the second excitation electrode 6 each include a single-layer electrode film. The first and second excitation electrodes 5 and 6 are made of Ru, for example. In this specification, “a certain member is made of a certain material” includes a case where the material includes small enough amounts of impurities not to significantly deteriorate the electric characteristics of the acoustic wave device. The materials of the first excitation electrode 5 and the second excitation electrode 6 are not limited to the above-described materials and may be a metal or an alloy including, for example, at least one of Al, Au, Cu, Cr, Ru, W, Mo, and Pt. Alternatively, the first excitation electrode 5 and the second excitation electrode 6 may each include a metal laminate film.

On the first major surface 4a of the piezoelectric layer 4, a first extended electrode 13 is provided. The first extended electrode 13 is extended from the first excitation electrode 5. That is, the first extended electrode 13 and the first excitation electrode 5 are integrally made of the same material. The layer structure of the first extended electrode 13 has the same arrangement of materials and thicknesses as the layer structure of the first excitation electrode 5. The “same arrangement of materials” means that, in each layer of each electrode, the main metal element is the same.

On the second major surface 4b of the piezoelectric layer 4, a second extended electrode 14 is provided. The second extended electrode 14 is extended from the second excitation electrode 6. That is, the second extended electrode 14 and the second excitation electrode 6 are integrally made of the same material. The layer structure of the second extended electrode 14 has the same arrangement of materials and thicknesses as the layer structure of the second excitation electrode 6. As noted above, the “same arrangement of materials” means that, in each layer of each electrode, the main metal element is the same.

On the first extended electrode 13, a first wiring electrode 7 is provided. On the second extended electrode 14, a second wiring electrode 8 is provided. The first and second wiring electrodes 7 and 8 are electrically coupled to, for example, other elements or the like. The thicknesses of the first and second wiring electrodes 7 and 8 are greater than the thicknesses of the first excitation electrode 5, the first extended electrode 13, the second excitation electrode 6, and the second extended electrode 14. The first and second wiring electrodes 7 and 8 thus have lower electric resistance.

In the first example embodiment, the first and second wiring electrodes 7 and 8 each include a metal laminate film. The first wiring electrode 7 includes a first layer 7a and a second layer 7b as a plurality of wiring electrode layers. The first layer 7a and the second layer 7b are stacked in this order from the piezoelectric layer 4 side. The first layer 7a is made of Cu, for example. The second layer 7b is made of Au, for example. The second wiring electrode 8 includes a first layer 8a and a second layer 8b as the plurality of wiring electrode layers. The first layer 8a and the second layer 8b are stacked in this order from the piezoelectric layer 4 side. The first layer 8a is made of Cu, for example. The second layer 8b is made of Au, for example.

The material of each layer of the first and second wiring electrodes 7 and 8 is not limited to the above materials and may be, for example, a metal or an alloy including at least one of Al, Au, Cu, Cr, Ru, W, Mo, and Pt, for example. The number of layers of each of the first and second wiring electrodes 7 and 8 is not limited to two and may be, for example, three or more. Alternatively, the first and second wiring electrodes 7 and 8 may each include a single-layer metal film.

The second excitation electrode 6, the second extended electrode 14, and the second wiring electrode 8 are embedded in the insulating layer 3. The insulating layer 3 needs to be provided on the second major surface 4b of the piezoelectric layer 4 so as to cover at least a portion of the second excitation electrode 6, the second extended electrode 14, and the second wiring electrode 8.

Within the insulating layer 3, an acoustic reflector is provided. More specifically, the acoustic reflector is a cavity portion 9 in the first example embodiment. The acoustic reflector may be a later-described acoustic reflection film. The cavity portion 9 overlaps the excitation region A in plan view. The energy of acoustic waves can be suitably confined in the piezoelectric layer 4 side. The “plan view” in the specification is the view from the direction corresponding to the upper side in FIG. 1. For example, in FIG. 1, the piezoelectric layer 4 side is the upper side, between the piezoelectric layer 4 side and the support substrate 2 side.

The cavity portion 9 only needs to overlap at least a portion of the excitation region A in plan view. For example, in plan view, a portion of the outer edge of the cavity portion 9 may be positioned outside the outer edge of the excitation region A while another portion of the outer edge of the cavity portion 9 is positioned inside the outer edge of the excitation region A. Preferably, the cavity portion 9 overlaps the entire or substantially the entire excitation region A in plan view. This can effectively confine the energy of acoustic waves in the piezoelectric layer 4 side.

The insulating layer 3 includes an intermediate portion 3a. More specifically, the intermediate portion 3a is a portion positioned between the cavity portion 9 and the second excitation electrode 6. The insulating layer 3 does not need to include the intermediate portion 3a. The cavity portion 9 as the acoustic reflector may be in contact with the second excitation electrode 6.

The first example embodiment has the following configurations:
1) The first and second wiring electrodes 7 and 8 are provided so as not to overlap the cavity portion 9 in plan view.
2) The layer structure of the first excitation electrode 5 has the same arrangement of materials from the piezoelectric layer 4 side as the layer structure of the second excitation electrode 6, and the layer structure of the first wiring electrode 7 has the same arrangement of materials from the piezoelectric layer 4 side as the layer structure of the second wiring electrode 8. Thus, the wiring resistance can be lowered, and the stress applied to the acoustic wave device 1 can be reduced as a whole. This will be described below.

In the acoustic wave device 1, the electrodes coupled to other elements include the first and second wiring electrodes 7 and 8 as well as the first and second extended electrodes 13 and 14. The wiring resistance thus can be lowered. In addition, the first and second wiring electrodes 7 and 8 are provided so as not to overlap the cavity portion 9 as the acoustic reflector in plan view. This can reduce the difference in the acoustic wave device 1 between stresses in the portion overlapping the cavity portion 9 in plan view and in the portion not overlapping the cavity portion 9. Thus, stress concentration is less likely to occur in the acoustic wave device 1, so that the stress applied to the acoustic wave device 1 can be reduced as a whole.

Furthermore, the layer structure of the first excitation electrode 5 has the same arrangement of materials from the piezoelectric layer 4 side as the layer structure of the second excitation electrode 6, and the layer structure of the first wiring electrode 7 has the same arrangement of materials from the piezoelectric layer 4 side as the layer structure of the second wiring electrode 8. As described above, the layer structure of the first excitation electrode 5 has the same arrangement of materials as the layer structure of the first extended electrode 13. The layer structure of the second excitation electrode 6 has the same arrangement of materials as the layer structure of the second extended electrode 14. Thus, the layer structure of a stack of the first extended electrode 13 and the first wiring electrode 7 has the same arrangement of materials from the piezoelectric layer 4 side as the layer structure of a stack of the second extended electrode 14 and the second wiring electrode 8. This can effectively reduce the difference between stresses applied to the first major surface 4a side of the piezoelectric layer 4 and the second major surface 4b side. The stresses applied to the first major surface 4a side and the second major surface 4b side thus can be effectively canceled with each other. Thus, the stress applied to the acoustic wave device 1 can be effectively reduced as a whole.

Preferably, the materials of the plurality of wiring electrode layers of each of the first and second wiring electrodes 7 and 8 are different from the materials of the first excitation electrode 5, the second excitation electrode 6, the first extended electrode 13, and the second extended electrode 14. More preferably, all of the metallic species that define the first and second wiring electrodes 7 and 8 have lower electric resistivities than the metallic species that define the first and second excitation electrodes 5 and 6 and the first and second extended electrodes 13 and 14. This can further lower the electric resistance of the first and second wiring electrodes 7 and 8.

Preferably, the layer structure of the first excitation electrode 5 has the same arrangement of materials and thicknesses from the piezoelectric layer 4 side as the layer structure of the second excitation electrode 6, and the layer structure of the first wiring electrode 7 has the same arrangement of materials and thicknesses from the piezoelectric layer 4 side as the layer structure of the second wiring electrode 8. This can further reduce the stress applied to the acoustic wave device 1 as a whole.

More specifically, the layer structure of the first excitation electrode 5 has the same arrangement of materials and thicknesses as the layer structure of the first extended electrode 13. The layer structure of the second excitation electrode 6 has the same arrangement of materials and thicknesses as the layer structure of the second extended electrode 14. The layer structure of the stack of the first extended electrode 13 and the first wiring electrode 7 has the same arrangement of materials and thicknesses from the piezoelectric layer 4 side as the layer structure of the stack of the second extended electrode 14 and the second wiring electrode 8. This can further reduce the difference between stresses applied to the first major surface 4a side of the piezoelectric layer 4 and the second major surface 4b side. The stresses applied to the first major surface 4a side and the second major surface 4b side thus can be more reliably canceled with each other. Thus, the stress applied to the acoustic wave device 1 can be further reduced as a whole.

In this specification, “electrodes have the same thickness” includes not only the case where the difference in thickness is 0% but also the case where the difference in thickness is, for example, not greater than about 20%. That is, thickness ta of one electrode is considered to be the same as thickness tb of the other electrode when ((ta−tb)/ta)×100 [%]≤about 20 [%]. Herein, ta>tb.

In the acoustic wave device 1, when acoustic waves are excited, heat is generated in the excitation region A. In the acoustic wave device 1, the heat dissipation can be improved. The thermal stress applied to the acoustic wave device 1 thus can be reduced as a whole. The details of the advantageous effects of improving the heat dissipation will be described below together with further details of the configuration of the first example embodiment.

FIG. 2 is a schematic plan view of the acoustic wave device according to the first example embodiment. FIG. 1 above is a schematic cross-sectional view along a line I-I in FIG. 2.

The first excitation electrode 5 and the first extended electrode 13 are integrally provided as described above. This electrode including the first excitation electrode 5 and the first extended electrode 13, which are integrally provided, is referred to as a first electrode. On the other hand, the electrode including the second excitation electrode 6 and the second extended electrode 14, which are integrally provided, is referred to as a second electrode. In this case, the portion of the first electrode that overlaps the second electrode in plan view is the first excitation electrode 5. Similarly, the portion of the second electrode that overlaps the first electrode in plan view is the second excitation electrode 6. In the first example embodiment, the entirety or substantially the entirety of the first excitation electrode 5 and the entirety or substantially the entirety of the second excitation electrode 6 overlap the excitation region A in plan view. The shapes of the first excitation electrode 5, the second excitation electrode 6, and the excitation region A are congruent in plan view.

The first excitation electrode 5 and the second excitation electrode 6 have a circular or substantially circular shape in plan view. The shape of the first and second excitation electrodes 5 and 6 in plan view is not limited to the above-described shape and may be circular, elliptical, semi-elliptical, or polygonal, for example.

The direction perpendicular or substantially perpendicular to the direction in which the first wiring electrode 7 extends is referred to as a first width direction. The dimension of the first wiring electrode 7 in the first width direction is denoted by D1, and the maximum dimension of the first excitation electrode 5 in the first width direction is denoted by E1. In the first example embodiment, the dimension D1 increases with the distance from the first excitation electrode 5 in the portion of the first wiring electrode 7 illustrated in FIG. 2. The first wiring electrode 7 thus includes a portion where D1>E1. This can improve the heat dissipation.

In plan view, the outer edge of the first wiring electrode 7 is positioned within the outer edge of the first extended electrode 13. Even if the first wiring electrode 7 or the first extended electrode 13 becomes misaligned during manufacturing of the acoustic wave device 1, therefore, the entire or substantially the entire first wiring electrode 7 can more reliably be provided on the first extended electrode 13. This can more reliably provide the structure in which the first wiring electrode 7 extended electrode is stacked on the first extended electrode 13, thus more reliably improving the heat dissipation.

The dimensional and positional relationship between the second excitation electrode 6, the second extended electrode 14, and the second wiring electrode 8 is the same or substantially the same as the dimensional and positional relationship between the first excitation electrode 5, the first extended electrode 13, and the first wiring electrode 7. More specifically, the outer edge of the second wiring electrode 8 is positioned within the outer edge of the second extended electrode 14 in plan view. Herein, the direction perpendicular or substantially perpendicular to the direction in which the second wiring electrode 8 extends is referred to as a second width direction. The dimension of the second wiring electrode 8 in the second width direction is denoted by D2, and the maximum dimension of the second excitation electrode 6 in the second width direction is denoted by E2. In the first example embodiment, the second width direction is parallel to the first width direction. The second wiring electrode 8 includes a portion where D2>E2. This can more reliably improve the heat dissipation.

The dimensional and positional relationship between the first excitation electrode 5, the first extended electrode 13, and the first wiring electrode 7 and the dimensional and positional relationship between the second excitation electrode 6, the second extended electrode 14, and the second wiring electrode 8 are not limited to the above-described relationships. Preferably, the acoustic wave device 1 has at least one of the configuration in which D1>E1 in at least a portion of the first wiring electrode 7 and the configuration in which D2>E2 in at least a portion of the second wiring electrode 8. More preferably, the acoustic wave device 1 includes both the configuration in which D1>E1 in at least a portion of the first wiring electrode 7 and the configuration in which D2>E2 in at least a portion of the second wiring electrode 8.

In the portion of the first wiring electrode 7 illustrated in FIG. 2, the dimension D1 of the first wiring electrode 7 varies. The first wiring electrode 7 may include a portion in which the dimension D1 is constant. In the portion of the first wiring electrode 7 illustrated in FIG. 2, the first wiring electrode 7 extends in one direction. The first wiring electrode 7 may also include a curved portion. In this case, the first width direction of a certain portion of the first wiring electrode 7 is the direction perpendicular or substantially perpendicular to the direction in which the certain portion extends. Comparison between dimensions of the first wiring electrode 7 and the first excitation electrode 5 in the first width direction needs to use the first width direction of the portion to be compared in the first wiring electrode 7.

In the same or substantially the same manner as the dimension D1 of the first wiring electrode 7, the dimension D2 of the second wiring electrode 8 varies in the portion of the second wiring electrode 8 illustrated in FIG. 2. The second wiring electrode 8 may include a portion in which the dimension D2 is constant. In the portion of the second wiring electrode 8 illustrated in FIG. 2, the second wiring electrode 8 extends in one direction. The second wiring electrode 8 may also include a curved portion. In this case, the second width direction of a certain portion of the second wiring electrode 8 is the direction perpendicular or substantially perpendicular to the direction in which the certain portion extends. Comparison between the dimensions of the second wiring electrode 8 and the second excitation electrode 6 in the second width direction needs to use the second width direction of the portion to be compared in the second wiring electrode 8.

Back to FIG. 1, plural bumps 15 are provided on the support substrate 2. The plural bumps 15 are electrically coupled to the first excitation electrode 5 or the second excitation electrode 6. The acoustic wave device 1 is bonded to a mounting substrate or the like by the plural bumps 15. The bumps 15 are an example of a member electrically coupling the acoustic wave device 1 to the outside. On the support substrate 2, an external terminal connector, for example, such as a land grid array (LGA), may be provided.

Heat generated in the excitation region A is transferred from the second excitation electrode 6, the second extended electrode 14, and the second wiring electrode 8 to the insulating layer 3. The heat is transferred through the insulating layer 3, the support substrate 2, and the bumps 15 to the outside. Thus, the heat dissipation can be improved.

The piezoelectric layer 4 is, for example, preferably made of any one of lithium tantalate, lithium niobate, and aluminum nitride. Lithium tantalate and lithium niobate are piezoelectric materials with a high dielectric constant. When the acoustic wave device 1 is used in a broadband filter, therefore, the piezoelectric layer 4 can be suitably made of lithium tantalate or lithium niobate. The acoustic wave device 1 has high heat dissipation due to its configuration described above. On the other hand, aluminum nitride is excellent in thermal conduction. When the piezoelectric layer 4 is made of aluminum nitride, the heat dissipation can be further improved.

The support substrate 2 preferably has a higher thermal conductivity than the piezoelectric layer 4 and the insulating layer 3. This can effectively improve the heat dissipation.

The support substrate 2 does not need to be provided. In this case, for example, an external terminal connector, such as the plural bumps 15, may be provided on a trace, such as the first wiring electrode 7, on the first major surface 4a side of the piezoelectric layer 4. The acoustic wave device 1 may be bonded to a mounting substrate or the like by such plural bumps 15. Alternatively, the acoustic wave device 1 may have a wafer level package (WLP) structure, for example. In this case, a support is provided on the piezoelectric layer 4, and on the support, a lid member is provided. On the lid member, an external terminal connector, such as the bumps 15, may be provided.

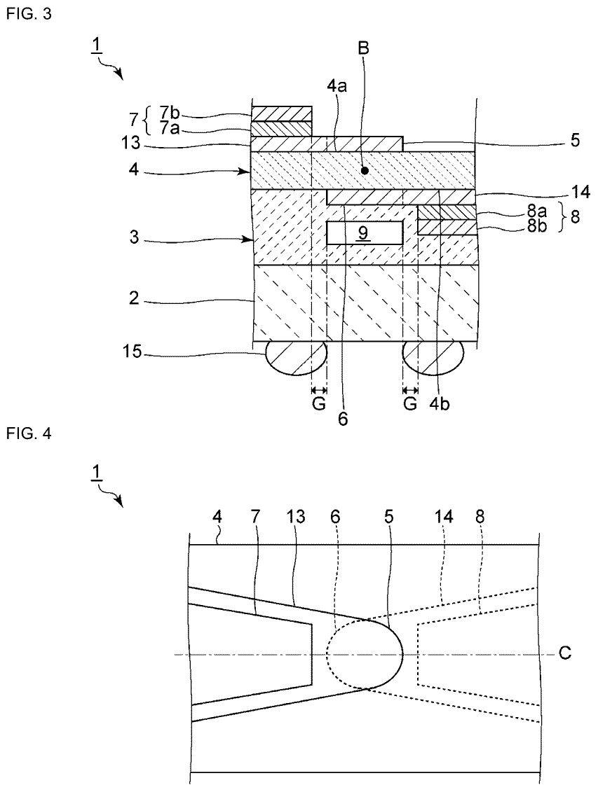

FIG. 3 is a schematic elevational cross-sectional view for explaining a symmetric structure in the first example embodiment. FIG. 4 is a schematic plan view for explaining another symmetric structure in the first example embodiment. One of dashed lines in FIG. 3 indicates the boundary between the first excitation electrode 5 and the first extended electrode 13. The other dashed line indicates the boundary between the second excitation electrode 6 and the second extended electrode 14. The same applies to each cross-sectional view in FIG. 3 and the subsequent drawings.

The cross-section illustrated in FIG. 3 is a cross-section passing through the piezoelectric layer 4, the first excitation electrode 5, the second excitation electrode 6, the first wiring electrode 7, and the second wiring electrode 8. In the cross-section illustrated in FIG. 3, the first excitation electrode 5 and the second excitation electrode 6 are point-symmetric with respect to the center of the piezoelectric layer 4 as a center B. In addition, the first wiring electrode 7 and the second wiring electrode 8 are point-symmetric with respect to the center of the piezoelectric layer 4 as the center B. This can effectively reduce or prevent variations in stress at locations in the acoustic wave device 1.

There are countless cross sections that pass through the piezoelectric layer 4, the first excitation electrode 5, the second excitation electrode 6, the first wiring electrode 7, and the second wiring electrode 8. Preferably, at least one of these cross-sections includes a portion in which the first excitation electrode 5 and the second excitation electrode 6 are point-symmetric and the first wiring electrode 7 and the second wiring electrode 8 are point-symmetric. This can effectively reduce or prevent variations in stress at locations in the acoustic wave device 1.

As illustrated in FIG. 4, the first excitation electrode 5 is line-symmetric with respect to a symmetry axis C in plan view. Similarly, the second excitation electrode 6 is line-symmetric with respect to the symmetry axis C. The first wiring electrode 7 is also line-symmetric with respect to the symmetry axis C. Furthermore, the second wiring electrode 8 is line-symmetric with respect to the symmetry axis C. In the first example embodiment, as described above, the symmetry axis C with respect to which the first excitation electrode 5 is line-symmetric, the symmetry axis C with respect to which the second excitation electrode 6 is line-symmetric, the symmetry axis C with respect to which the first wiring electrode 7 is line-symmetric, and the symmetry axis C with respect to which the second wiring electrode 8 is line-symmetric coincide with each other in plan view. This can effectively reduce or prevent variations in stress at locations in the acoustic wave device 1.

As described above, each of the first and second wiring electrodes 7 and 8 may include a curved portion. In this case, preferably, the symmetry axis with respect to which a portion of the first wiring electrode 7 is line-symmetric is the symmetry axis C, and the symmetry axis with respect to which a portion of the second wiring electrode 8 is line-symmetric is the aforementioned symmetry axis C. Preferably, the symmetry axis C of the first excitation electrode 5, the symmetry axis C of the second excitation electrode 6, the symmetry axis C of at least a part of the first wiring electrode 7, and the symmetry axis C of at least a portion of the second wiring electrode 8 coincide with each other in plan view. This can effectively reduce or prevent variations in stress at locations in the acoustic wave device 1.

As illustrated in FIG. 3, in the first example embodiment, the first wiring electrode 7 and the second wiring electrode 8 are provided so as not to overlap the cavity portion 9 as the acoustic reflector in plan view. This can reduce the difference between stresses in the portion overlapping the cavity portion 9 in plan view and in the portion not overlapping the cavity portion 9 in the acoustic wave device 1. Furthermore, in the first example embodiment, the cavity portion 9 faces the first wiring electrode 7 and the second wiring electrode 8 with gaps G therebetween in plan view. Even if the first wiring electrode 7, the second wiring electrode 8, or the cavity portion 9 becomes misaligned during manufacturing of the acoustic wave device 1, therefore, the first and second wiring electrodes 7 and 8 and the cavity portion 9 can be more reliably provided so as not to overlap each other in plan view. This can more reliably reduce or prevent variations in stress at locations in the acoustic wave device 1.

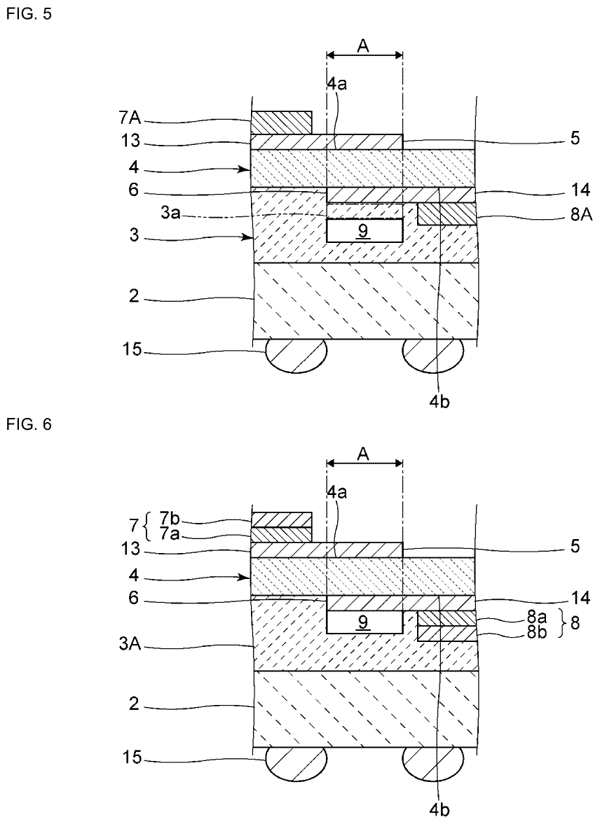

As described above, the first and second wiring electrodes 7 and 8 do not need include a metal laminate film. In a first modification of the first example embodiment illustrated in FIG. 5, for example, a first wiring electrode 7A and a second wiring electrode 8A each include a single-layer metal film. In this case, similarly to the first example embodiment, the wiring resistance can be lowered, and the stress applied can be reduced as a whole.

The insulating layer 3 do not need to include the intermediate portion 3a as described above. In a second modification of the first example embodiment illustrated in FIG. 6, for example, the insulating layer 3A does not include an intermediate portion. The second excitation electrode 6 is in contact with the cavity portion 9 as the acoustic reflector. In this case, similarly to the first example embodiment, the wiring resistance can be lowered, and the stress applied can be reduced as a whole.

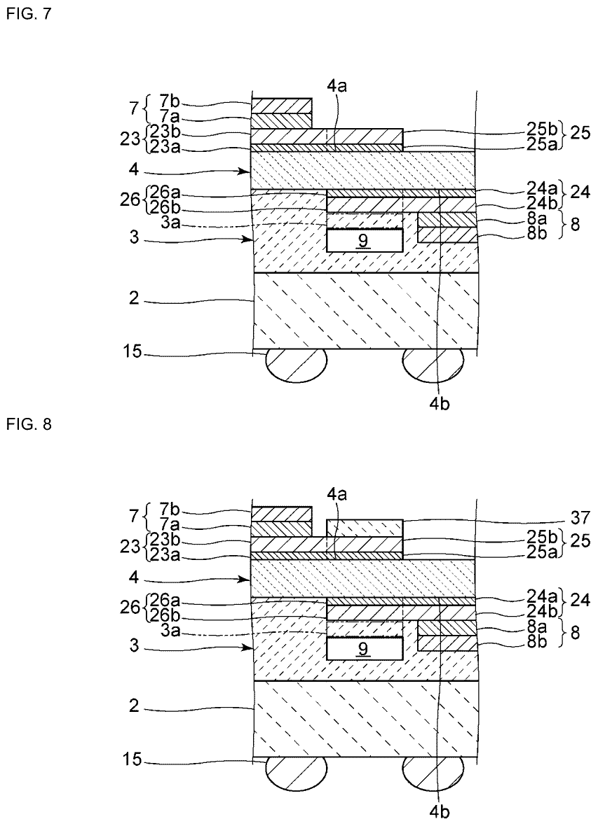

FIG. 7 is a schematic elevational cross-sectional view of an acoustic wave device according to a second example embodiment of the present invention.

The second example embodiment is different from the first example embodiment in that a first excitation electrode 25, a second excitation electrode 26, a first extended electrode 23, and a second extended electrode 24 each include a metal laminate film. The acoustic wave device of the second example embodiment has the same or substantially the same configuration as the acoustic wave device 1 of the first example embodiment other than the above-described point.

The first excitation electrode 25 includes a first layer 25a and a second layer 25b as a plurality of electrode layers. The first extended electrode 23 includes a first layer 23a and a second layer 23b. The first excitation electrode 25 and the first extended electrode 23 are integrally made of the same materials. The layer structure of the first excitation electrode 25 has the same arrangement of materials and thicknesses as the layer structure of the first extended electrode 23.

More specifically, in the first excitation electrode 25, the first layer 25a and the second layer 25b are stacked in this order from the piezoelectric layer 4 side in the second example embodiment. The first layer 25a is made of W, for example. The second layer 25b is made of Al, for example. In the first extended electrode 23, similarly, the first layer 23a and the second layer 23b are stacked in this order from the piezoelectric layer 4 side. The first layer 23a is made of W, for example. The second layer 23b is made of Al, for example. The material of each layer of the first excitation electrode 25 and first extended electrode 23 may be a metal or an alloy including at least one of Al, Au, Cu, Cr, Ru, W, Mo, and Pt, for example. Thus, the first layers 25a and 23a may be made of Pt, for example.

The relationship between the second excitation electrode 26 and the second extended electrode 24 is the same or substantially the same as the relationship between the first excitation electrode 25 and the first extended electrode 23. Specifically, the second excitation electrode 26 includes a first layer 26a and a second layer 26b as the plurality of electrode layers. The second extended electrode 24 includes a first layer 24a and a second layer 24b. The second excitation electrode 26 and the second extended electrode 24 are integrally made of the same materials. The layer structure of the second excitation electrode 26 has the same arrangement of materials and thicknesses as the layer structure of the second extended electrode 24.

More specifically, in the second excitation electrode 26, the first layer 26a and the second layer 26b are stacked in this order from the piezoelectric layer 4 side. The first layer 26a is made of W. The second layer 26b is made of Al. Similarly, in the second extended electrode 24, the first layer 24a and the second layer 24b are stacked in this order from the piezoelectric layer 4 side. The first layer 24a is made of W. The second layer 24b is made of Al.

In the second example embodiment, similarly to the first example embodiment, the first wiring electrode 7 and the second wiring electrode 8 are provided so as not to overlap the cavity portion 9 in plan view. Furthermore, the layer structure of the first excitation electrode 25 has the same arrangement of materials and thicknesses from the piezoelectric layer 4 side as the layer structure of the second excitation electrode 26, and the layer structure of the first wiring electrode 7 has the same arrangement of materials and thicknesses from the piezoelectric layer 4 side as the layer structure of the second wiring electrode 8. The layer structure of the stack of the first extended electrode 23 and the first wiring electrode 7 has the same arrangement of materials and thicknesses from the piezoelectric layer 4 side as the layer structure of the stack of the second extended electrode 24 and the second wiring electrode 8. Such configurations can lower the wiring resistance and reduce the stress applied to the acoustic wave device as a whole.

The number of layers of each of the first excitation electrode 25, the second excitation electrode 26, the first extended electrode 23, and the second extended electrode 24 is not limited to two and may be, for example, three or more. The number of layers of each of the first excitation electrode 25, the second excitation electrode 26, the first extended electrode 23, and the second extended electrode 24 may be the same as or similarly to the first example embodiment. In the acoustic wave device of the present invention, the number of layers of each of the first excitation electrode, the second excitation electrode, the first extended electrode, and the second extended electrode is not limited.

FIG. 8 is a schematic elevational cross-sectional view of an acoustic wave device according to a third example embodiment of the present invention.

The third example embodiment is different from the second example embodiment in that a dielectric film 37 is provided on the first excitation electrode 25. The configuration of the acoustic wave device of the third example embodiment is the same or substantially the same as that of the acoustic wave device of the second example embodiment other than the above-described point.

The dielectric film 37 is provided on the portion of the first excitation electrode 25 that overlaps the cavity portion 9 as the acoustic reflector in plan view. The dielectric film 37 is made of the same material as the insulating layer 3. The dielectric film 37 has the same thickness as the intermediate portion 3a of the insulating layer 3. In the third example embodiment, thus, the layer structure of the stack of the first excitation electrode 25 and the dielectric film 37 has the same arrangement of materials and thicknesses as the layer structure of the stack of the second excitation electrode 26 and the intermediate portion 3a. In addition, the electrodes of the third example embodiment are configured in the same manner as those of the second example embodiment. Thus, the wiring resistance can be lowered, and the stress applied to the acoustic wave device can be effectively reduced as a whole.

In this specification, “the thickness of the dielectric film is the same as that of the intermediate portion” includes not only the case where the difference in thickness is 0% but also the case where the difference in thickness is, for example, not greater than about 20%. That is, thickness tc of one of the dielectric film and the intermediate portion is considered to be the same as thickness td of the other one when ((tc−td)/tc)×100 [%]≤about 20 [%]. Herein, tc>td.

The portion for which the dielectric film 37 is provided is not limited to the above-described portion. For example, the dielectric film 37 may cover at least a portion of the first excitation electrode 25, the first extended electrode 23, and the first wiring electrode 7. The dielectric film 37 may cover the entire or substantially the entire surface of the first excitation electrode 25, the first extended electrode 23, and the first wiring electrode 7. The dielectric film 37 does not need to be made of the same material as the insulating layer 3. The dielectric film 37 does not need to have the same thickness as the intermediate portion 3a of the insulating layer 3. Alternatively, when the dielectric film 37 is provided, the insulating layer 3 does not need to include the intermediate portion 3a.

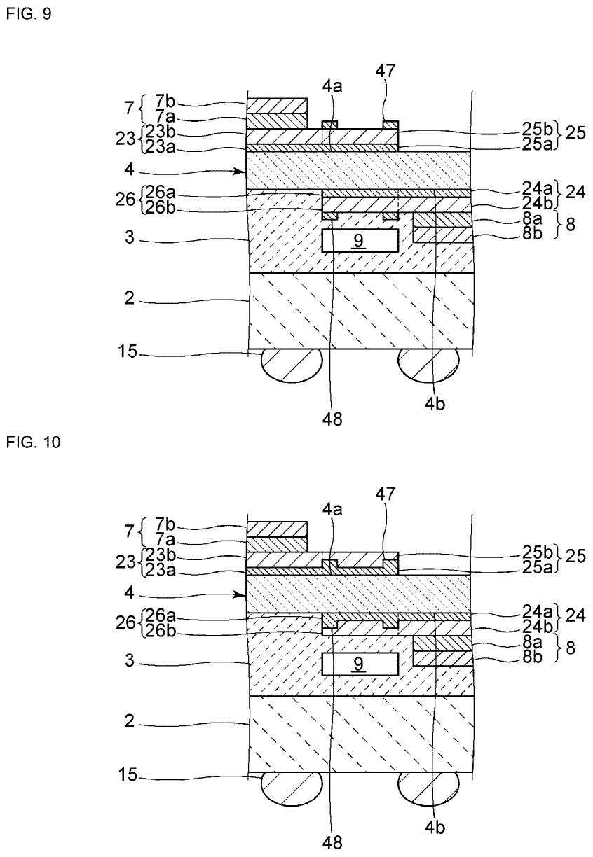

FIG. 9 is a schematic elevational cross-sectional view of an acoustic wave device according to a fourth example embodiment of the present invention.

The fourth example embodiment is different from the second example embodiment in that a first peripheral structure 47 is provided on the first excitation electrode 25 and a second peripheral structure 48 is provided on the second excitation electrode 26. The configuration of the acoustic wave device of the fourth example embodiment is the same or substantially the same as that of the acoustic wave device of the second example embodiment other than the above-described points.

The first peripheral structure 47 is an electrode provided on the outer edge of the second layer 25b of the first excitation electrode 25. More specifically, the outer edge of the first peripheral structure 47 overlaps the outer edge of the first excitation electrode 25 in plan view. The first peripheral structure 47 has an annular or substantially annular shape in plan view. The first peripheral structure 47 and the first excitation electrode 25 may be integrally made of the same material.

The second peripheral structure 48 is an electrode provided on the outer edge of the second layer 26b of the second excitation electrode 26. The second peripheral structure 48 has an annular or substantially annular shape in plan view. More specifically, the outer edge of the second peripheral structure 48 overlaps the outer edge of the second excitation electrode 26 in plan view. The second peripheral structure 48 and the second excitation electrode 26 may be integrally made of the same material.

The shapes of the first excitation electrode 25 and the second excitation electrode 26 are congruent in plan view. The shapes of the first peripheral structure 47 and the second peripheral structure 48 are also congruent in plan view. The entirety or substantially the entirety of the first peripheral structure 47 overlaps the entirety or substantially the entirety of the second peripheral structure 48 in plan view. Furthermore, the thickness and the material of the first peripheral structure 47 are the same as those of the second peripheral structure 48.

The shapes of the first peripheral structure 47 and the second peripheral structure 48 in plan view do not need to be congruent in plan view. At least a portion of the first peripheral structure 47 needs to overlap at least a portion of the second peripheral structure 48.

In the fourth example embodiment, the first peripheral structure 47 and the second peripheral structure 48 are symmetric in a cross-section along a thickness direction of the piezoelectric layer 4. More specifically, in the cross-section, the first peripheral structure 47 and the second peripheral structure 48 are line-symmetric with respect to a symmetry axis that is positioned in the center of the piezoelectric layer 4 in the thickness direction and extends in the direction perpendicular to the thickness direction. In addition, the electrodes of the fourth example embodiment are configured in the same manner as those of the second example embodiment. Thus, the wiring resistance can be lowered, and the stress applied to the acoustic wave device can be effectively reduced as a whole.

As described above, the first and second outer peripheral portions 47 and 48 each have an annular or substantially annular shape in plan view. The first and second outer peripheral portions 47 and 48 do not need to be annular. The first peripheral structure 47 needs to overlap at least a portion of the outer edge of the first excitation electrode 25 in plan view. The second peripheral structure 48 needs to overlap at least a portion of the outer edge of the second excitation electrode 26 in plan view. The first and second peripheral structures 47 and 48 each may have a curved shape, not an annular shape, in plan view. Alternatively, when the first and second excitation electrodes 25 and 26 each have a polygonal shape in plan view, the first and second peripheral structures 47 and 48 may each have, for example, a linear shape, an L shape, a U shape, or the like in plan view.

The configurations and positions of the first and second peripheral structures 47 and 48 are not limited to those described above. Hereinafter, first to third modifications of the fourth example embodiment will be illustrated, which are different from the fourth example embodiment only in the configurations or positions of the first and second peripheral structures 47 and 48. Furthermore, a fourth modification will be illustrated, which is different from the fourth example embodiment only in the configurations or positions of the first and second peripheral structures 47 and 48 and layer structures of the first and second excitation electrodes 23 and 24. In the first to fourth modifications, similarly to the fourth example embodiment, the wiring resistance can be lowered, and the stress applied to the acoustic wave device can be effectively reduced as a whole.

In the first modification illustrated in FIG. 10, the first peripheral structure 47 is provided on the first layer 25a of the first excitation electrode 25 and is embedded in the second layer 25b. In the first modification, the first peripheral structure 47 and the first layer 25a are integrally made of the same material. However, the first peripheral structure 47 and the first layer 25a may be separately made of different materials.

Similarly, the second peripheral structure 48 is provided on the first layer 26a of the second excitation electrode 26 and is embedded in the second layer 26b. The second peripheral structure 48 and the first layer 26a are integrally made of the same material. However, the second peripheral structure 48 and the first layer 26a may be separately made of different materials.

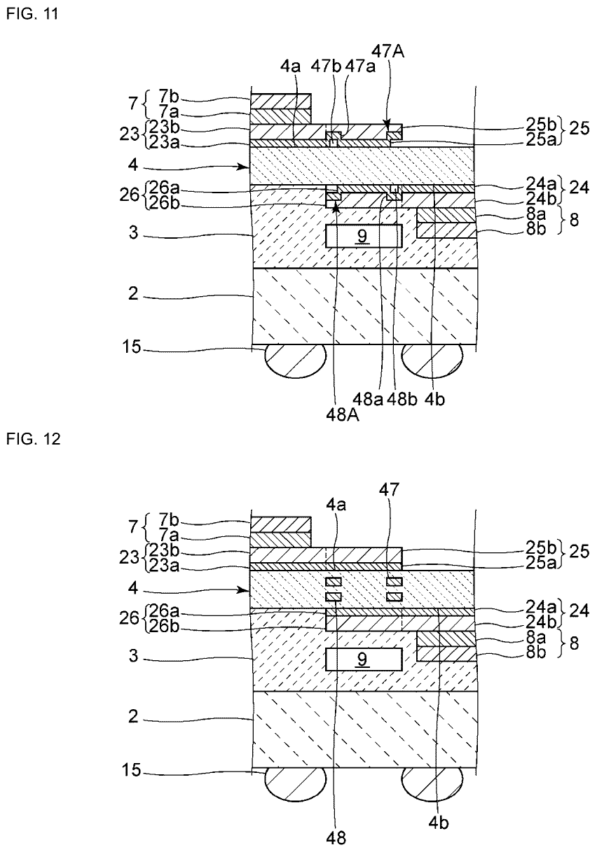

In the second modification illustrated in FIG. 11, a first peripheral structure 47A and the first layer 25a of the first excitation electrode 25 are integrated. A portion of the first peripheral structure 47A is embedded in the second layer 25b of the first excitation electrode 25. In the second modification, the first peripheral structure 47A includes an electrode portion 47a and a space portion 47b. The space portion 47b is a space overlapping the electrode portion 47a in plan view. The outer edge of the electrode portion 47a overlaps the outer edge of the first excitation electrode 25 in plan view. The electrode portion 47a is embedded in the second layer 25b. A portion of the outer edge of the space portion 47b is in contact with the outside. Another portion of the outer edge of the space portion 47b is in contact with the first layer 25a.

In the second modification, the space portion 47b of the first peripheral structure 47A is opened to the outside. On the first major surface 4a of the piezoelectric layer 4, a dielectric film may be provided so as to cover the first excitation electrode 25. In this case, the outer edge of the space portion 47b is in contact with the first extended electrode 23 and the dielectric film.

A second peripheral structure 48A and the first layer 26a of the second excitation electrode 26 are integrated. A portion of the second peripheral structure 48A is embedded in the second layer 26b of the second excitation electrode 26. In the second modification, the second peripheral structure 48A includes an electrode portion 48a and a space portion 48b. The space portion 48b is a space overlapping the electrode portion 48a in plan view. The outer edge of the electrode portion 48a overlaps the outer edge of the second excitation electrode 26 in plan view. The electrode portion 48a is embedded in the second layer 26b. A portion of the outer edge of the space portion 48b is in contact with the insulating layer 3. Another portion of the outer edge of the space portion 48b is in contact with the first layer 26a.

To provide the first peripheral structure 47A, for example, a sacrificial layer may be provided on the first major surface 4a of the piezoelectric layer 4, and then the electrode portion 47a may be provided on the sacrificial layer. In this process, the electrode portion 47a, the first layer 25a of the first excitation electrode 25, and the first layer 23a of the first extended electrode 23 may be simultaneously formed. The sacrificial layer is then removed to form the space portion 47b. Thus, the first peripheral structure 47A can be obtained. To provide the second peripheral structure 48A, a sacrificial layer may be formed and removed in the same or similar manner.

The space portion 47b of the first peripheral structure 47A may be filled with a dielectric, for example. That is, the first peripheral structure 47A may be a stack of a dielectric layer and the electrode portion 47a. The dielectric layer may be made of, for example, silicon oxide or the like. In this case, to provide the first peripheral structure 47A, for example, the dielectric layer may be formed on the first major surface 4a of the piezoelectric layer 4, and then the electrode portion 47a may be formed on the dielectric layer. Similarly, the second peripheral structure 48A may be a stack of a dielectric layer and the electrode portion 48a. In this case, to provide the second peripheral structure 48A, for example, the dielectric layer may be formed on the second major surface 4b of the piezoelectric layer 4, and then the electrode portion 48a may be formed on the dielectric layer.

In the third modification illustrated in FIG. 12, the first and second peripheral structures 47 and 48 are provided within the piezoelectric layer 4. The positions of the first and second peripheral structures 47 and 48 in plan view in the third modification are the same or substantially the same as the positions of the first and second peripheral structures 47 and 48 in plan view in the fourth example embodiment. That is, the outer edges of the first and second peripheral structures 47 and 48 overlap the outer edges of the first and second excitation electrodes 25 and 26 in plan view.

The piezoelectric layer 4 of the third modification may be a stack, for example. Specifically, the piezoelectric layer 4 may be a stack of a layer in which the first peripheral structure 47 or the second peripheral structure 48 is embedded and a layer in which neither the first peripheral structure 47 nor the second peripheral structure 48 is embedded.

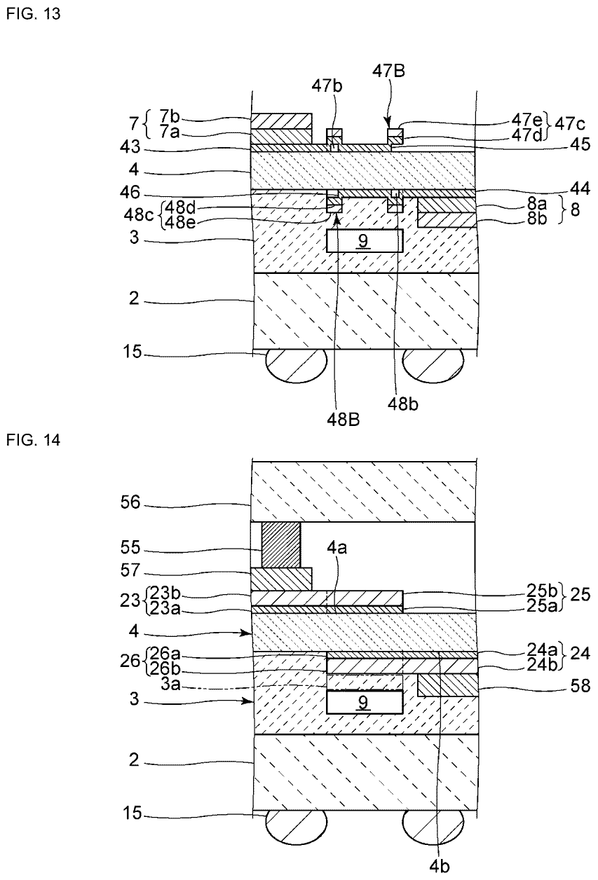

When the first peripheral structure 47A includes the electrode portion 47a and the space portion 47b like the second modification illustrated in FIG. 11, the electrode portion 47a does not need to be embedded in the first excitation electrode 25. In the fourth modification of the fourth example embodiment illustrated in FIG. 13, for example, an electrode portion 47c of a first peripheral structure 47B is not embedded in the first excitation electrode 45. Specifically, the first excitation electrode 45 and the first extended electrode 43 each include a single-layer metal film similarly to the first example embodiment. Between the first excitation electrode 45 and the first extended electrode 43, a portion of a space portion 47b of the first peripheral structure 47B is provided. The first excitation electrode 45 and the first extended electrode 43 are coupled by the electrode portion 47c of the first peripheral structure 47B.

The electrode portion 47c includes a metal laminate film. Specifically, the electrode portion 47c includes a first layer 47d and a second layer 47e. The first layer 47d of the electrode portion 47c couples the first excitation electrode 45 and the first extended electrode 43. The second layer 47e is provided only on the first layer 47d.

Similarly, the second excitation electrode 46 and the second extended electrode 44 each include a single-layer metal film. Between the second excitation electrode 46 and the second extended electrode 44, a portion of a space portion 48b of the second peripheral structure 48B is provided. The electrode portion 48c of the second peripheral structure 48B includes a metal laminate film. Specifically, the electrode portion 48c includes a first layer 48d and a second layer 48e. The first layer 48d of the electrode portion 48c couples the second excitation electrode 46 and the second extended electrode 44. The second layer 48e is provided only on the first layer 48d. In the fourth modification, as with the fourth example embodiment, the wiring resistance can be lowered, and the stress applied to the acoustic wave device can be effectively reduced as a whole.

In the first to fourth modifications, the shapes of the first peripheral structure and the second peripheral structure are congruent in plan view. The entirety or substantially the entirety of the first peripheral structure overlaps the entirety or substantially the entirety of the second peripheral structure in plan view. The shapes of the first peripheral structure and the second peripheral structure do not need to be congruent in plan view. At least a portion of the first peripheral structure needs to overlap at least a portion of the second peripheral structure in plan view.

In the fourth example embodiment and the modifications thereof, both of the first and second peripheral structures are provided. It is necessary to provide at least one of the first peripheral structure and the second peripheral structure as the peripheral structure. For example, when only the first peripheral structure is provided, between the first peripheral structure and the second peripheral structure, the portion where the first peripheral structure is provided is a portion of the portion overlapping the excitation region in plan view. Even in this case, therefore, the stress applied to the acoustic wave device can be effectively reduced as a whole. The same applies to the case where only the second peripheral structure is provided, between the first peripheral structure and the second peripheral structure. The configuration in which at least one of the first peripheral structure and the second peripheral structure is provided can be also used in another example embodiment of the present invention besides the fourth example embodiment and the modifications thereof.

FIG. 14 is a schematic elevational cross-sectional view of an acoustic wave device according to a fifth example embodiment of the present invention.

The fifth example embodiment is different from the second example embodiment in that a support 55 and a lid member 56 are provided. The fifth example embodiment is different from the second example embodiment also in that a first wiring electrode 57 and a second wiring electrode 58 each include a single-layer metal film. The configuration of the acoustic wave device of the fifth example embodiment is the same or substantially the same as that of the acoustic wave device of the second example embodiment other than the above-described points.

The support 55 is provided on the first wiring electrode 57. The support 55 is a metal column in the fifth example embodiment. The support 55 may be, for example, a via electrode penetrating a column member made of resin.

On the first major surface 4a of the piezoelectric layer 4, a frame-shaped support is provided (not illustrated). The support includes an opening. The first excitation electrode 25, the second excitation electrode 26, the first wiring electrode 57, the second wiring electrode 58, and the support 55 are provided within the opening in plan view. On the frame-shaped support and the columnar support 55, the lid member 56 is provided. The lid member 56 closes the opening of the frame-shaped support.

The support 55 can be made of, for example, a metal such as Cu or Au or an alloy thereof. The lid member 56 can be made of, for example, a semiconductor, such as silicon, ceramics, such as aluminum nitride, or the like.

In the fifth example embodiment, heat generated in the excitation region can be transferred to the outside through the first extended electrode 23, the first wiring electrode 57, the support 55, and the lid member 56. The heat dissipation therefore can be effectively improved.

The support 55 and the lid member 56 may be electrically coupled to each other as long as the electric characteristics of the acoustic wave device are not significantly deteriorated. Alternatively, the support 55 and the lid member 56 do not need to be electrically coupled to each other. For example, an insulating film may be provided between the support 55 and the lid member 56.

Preferably, the support 55 and the lid member 56 have higher thermal conductivities than the piezoelectric layer 4. This can further improve the heat dissipation.

The electrodes of the fifth example embodiment are configured in the same or substantially the same manner as the second example embodiment other than that the first and second wiring electrodes 57 and 58 each include a single-layer metal film. Thus, the wiring resistance can be lowered, and the stress applied to the acoustic wave device can be effectively reduced as a whole.

On the lid member 56, an external terminal connector, such as the bumps 15, may be provided.

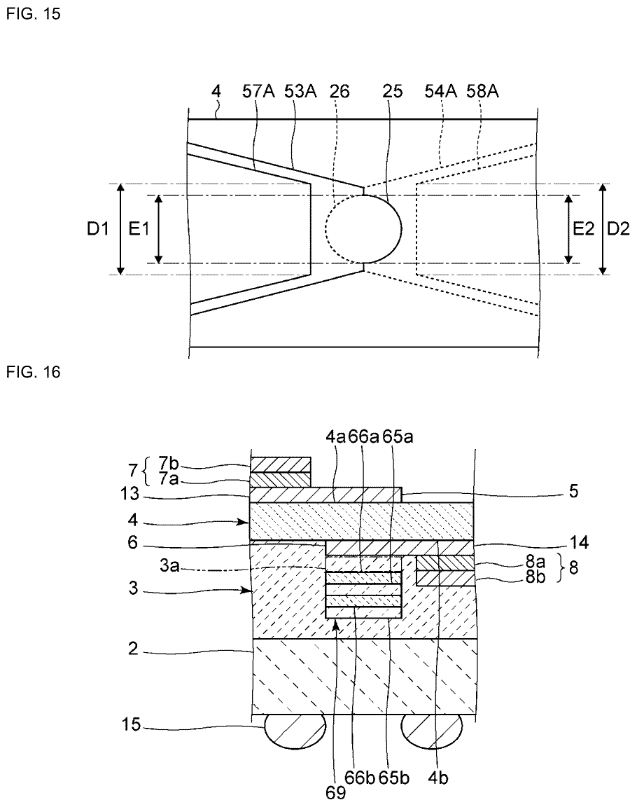

FIG. 15 is a schematic plan view of an electrode configuration on the piezoelectric layer in a modification of the fifth example embodiment.

This modification is different from the fifth example embodiment in dimensions of a first wiring electrode 57A and a first extended electrode 53A in the first width direction and dimensions of a second wiring electrode 58A and a second extended electrode 54A in the second width direction. Herein, in the same or similar manner as described above, the electrode including the first excitation electrode 25 and the first extended electrode 53A, which are integrated, is referred to as a first electrode. The electrode including the second excitation electrode 26 and the second extended electrode 54A, which are integrated, is referred to as a second electrode. In this modification, the minimum dimension of the first electrode in the first width direction is greater than the maximum dimension E1 of the first excitation electrode 25 in the first width direction. In every portion of the first wiring electrode 57A, the dimension D1 in the first width direction is greater than the maximum dimension E1 of the first excitation electrode 25 in the first width direction.

Similarly, the minimum dimension of the second electrode in the second width direction is greater than the maximum dimension E2 of the second excitation electrode 26 in the second width direction. In every portion of the second wiring electrode 58A, the dimension D2 in the second width direction is greater than the maximum dimension E2 of the second excitation electrode 26 in the second width direction.

Preferably, the acoustic wave device has at least one of the configuration in which D1>E1 in every portion of the first wiring electrode 57A and the configuration in which D2>E2 in every portion of the second wiring electrode 58A. More preferably, the acoustic wave device has both the configuration in which D1>E1 in every portion of the first wiring electrode 57A and the configuration in which D2>E2 in every portion of the second wiring electrode 58A like this modification. This can further improve the heat dissipation.

FIG. 16 is a schematic elevational cross-sectional view of an acoustic wave device according to a sixth example embodiment of the present invention.

The sixth example embodiment is different from the first example embodiment in that the acoustic reflector is an acoustic reflection film 69, which is provided within the insulating layer 3. The configuration of the acoustic wave device of the sixth example embodiment is the same or substantially the same as that of the acoustic wave device 1 of the first example embodiment other than the above-described point.

The acoustic reflection film 69 is a stack of plural acoustic impedance layers. More specifically, the acoustic reflection film 69 includes plural low-acoustic impedance layers and plural high-acoustic impedance layers. Each low-acoustic impedance layer is a layer having a relatively low acoustic impedance. The plural low-acoustic impedance layers of the acoustic reflection film 69 include low-acoustic impedance layers 65a and 65b. Each high-acoustic impedance layer is a layer having a relatively high acoustic impedance. The plural high-acoustic impedance layers of the acoustic reflection film 69 include high-acoustic impedance layers 66a and 66b. The low-acoustic impedance layers and the high-acoustic impedance layers are alternately stacked on top of each other.

The high-acoustic impedance layer 66a is a layer positioned closest to the piezoelectric layer 4 in the acoustic reflection film 69. The intermediate portion 3a of the insulating layer 3 is positioned between the high-acoustic impedance layer 66a and the piezoelectric layer 4. The low-acoustic impedance layer 65a may be a layer positioned closest to the piezoelectric layer 4 in the acoustic reflection film 69, for example.

The acoustic reflection film 69 includes, for example, two low-acoustic impedance layers and two high-acoustic impedance layers. The acoustic reflection film 69 only needs to include at least one low-acoustic impedance layer and at least one high-acoustic impedance layer.

The low-acoustic impedance layer can be made of, for example, silicon oxide, aluminum, or the like. The high-acoustic impedance layer can be made of, for example, a metal, such as platinum or tungsten, or a dielectric, such as aluminum nitride or silicon nitride.

By providing the acoustic reflection film 69, the energy of acoustic waves can be effectively confined in the piezoelectric layer 4 side. In addition, the electrodes of the sixth example embodiment are configured in the same or substantially the same manner as those of the first example embodiment. Thus, the wiring resistance can be lowered, and the stress applied can be effectively reduced as a whole.

When the dielectric film 37 is provided on the first excitation electrode 5 in the same or substantially the same manner as the third example embodiment illustrated in FIG. 8, preferably, the dielectric film 37 is made of the same material as the insulating layer 3. More preferably, the dielectric film 37 has the same thickness as the intermediate portion 3a of the insulating layer 3. This can effectively reduce the stress applied to the acoustic wave device as a whole.

The acoustic wave devices according to example embodiments of the present invention can each be used in, for example, filter devices. An example thereof will be illustrated below.

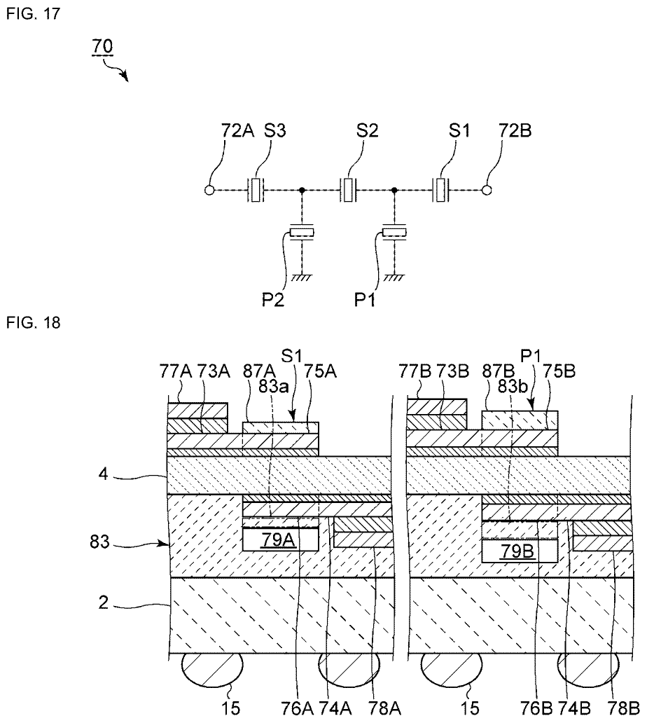

FIG. 17 is a circuit diagram of a filter device according to a seventh example embodiment of the present invention.

A filer device 70 is, for example, a ladder filter. The filter device 70 includes a first signal terminal 72A, a second signal terminal 72B, and plural serial and parallel arm resonators as a plurality of resonators. In the filter device 70 of the seventh example embodiment, all of the serial arm resonators and all of the parallel arm resonators are acoustic wave devices according to an example embodiment of the present invention. At least one of the resonators needs to be an acoustic wave device according to an example embodiment of the present invention.

The first signal terminal 72A is an antenna terminal in the seventh example embodiment. The antenna terminal is coupled to an antenna. The first signal terminal 72A and the second signal terminal 72B may be configured as, for example, an electrode land or a trace.

The plural serial arm resonators of the seventh example embodiment are specifically a serial arm resonator S1, a serial arm resonator S2, and a serial arm resonator S3. The plural serial arm resonators are coupled to each other in series between the first signal terminal 72A and the second signal terminal 72B. The plural parallel arm resonators of the seventh example embodiment are specifically a parallel arm resonator P1 and a parallel arm resonator P2. The parallel arm resonator P1 is coupled to between the ground potential and a connection point between the serial arm resonator S1 and the serial arm resonator S2. The parallel arm resonator P2 is coupled to between the ground potential and a connection point between the serial arm resonator S2 and the serial arm resonator S3.

The circuit configuration of the filter device according to the present invention is not limited to the above-described configuration. When the filter device is, for example, a ladder filter, the filter device needs to include at least one serial arm resonator and at least one parallel arm resonator. Alternatively, the filter device may include a longitudinally coupled resonator acoustic wave filter. In this case, the filter device needs to include at least one acoustic wave device according to an example embodiment of the present invention as a serial arm resonator or a parallel arm resonator.

FIG. 18 is schematic elevational cross-sectional views of a serial arm resonator and a parallel arm resonator in the seventh example embodiment. In FIG. 18, the serial arm resonator S1 and the parallel arm resonator P1 are schematically illustrated side by side. The arrangement of the resonators is not limited.

In the seventh example embodiment, the plural resonators share the piezoelectric layer 4 and an insulating layer 83. Each resonator may include a different piezoelectric layer 4 and a different insulating layer 83. Each resonator is configured in the same or substantially the same manner as the third example embodiment. More specifically, the serial arm resonator S1 includes a first excitation electrode 75A, a second excitation electrode 76A, a first extended electrode 73A, a second extended electrode 74A, a first wiring electrode 77A, a second wiring electrode 78A, and a dielectric film 87A. A cavity portion 79A is provided in the portion of the insulating layer 83 that overlaps the excitation region of the serial arm resonator S1 in plan view. The first and second wiring electrodes 77A and 78A of the serial arm resonator S1 are disposed so as not to overlap the cavity portion 79A in plan view. The insulating layer 83 includes an intermediate portion 83a. The intermediate portion 83a is positioned between the cavity portion 79A and the second excitation electrode 76A.

The parallel arm resonator P1 includes a first excitation electrode 75B, a second excitation electrode 76B, a first extended electrode 73B, a second extended electrode 74B, a first wiring electrode 77B, a second wiring electrode 78B, and a dielectric film 87B. A cavity portion 79B is provided in the portion of the insulating layer 83 that overlaps the excitation region of the parallel arm resonator P1 in plan view. The first and second wiring electrodes 77B and 78B of the parallel arm resonator P1 are disposed so as not to overlap the cavity portion 79B in plan view. The insulating layer 83 includes the intermediate portion 83b. The intermediate portion 83b is positioned between the cavity portion 79B and the second excitation electrode 76B.

The other resonators are configured in the same or substantially the same manner as the serial arm resonator S1 or the parallel arm resonator P1 (not illustrated). Specifically, a cavity portion is provided in the portion of the insulating layer 83 that overlaps the excitation region of each resonator in plan view. The first and second wiring electrodes of each resonator are disposed so as not to overlap the cavity portion in plan view. The insulating layer 83 includes plural intermediate portions in addition to the intermediate portions 83a and 83b. Each of these intermediate portions is positioned between the cavity portion and the second excitation electrode in the corresponding resonator.

Each resonator includes the first and second wiring electrodes, so that the wiring resistance of the filter device 70 is lowered.

As illustrated in FIG. 18, each layer of the first excitation electrode 75A in the serial arm resonator S1 has a different thickness from the corresponding layer of the first excitation electrode 75B in the parallel arm resonator P1. More specifically, each layer of the first excitation electrode 75A in the serial arm resonator S1 is thinner than the corresponding layer of the first excitation electrode 75B in the parallel arm resonator P1. In addition, the dielectric film 87A of the serial arm resonator S1 is thinner than the dielectric film 87B of the parallel arm resonator P1. When each of the first and second excitation electrodes 75A and 75B includes a first layer and a second layer, the second layer of the first excitation electrode 75A needs to be thinner than the second layer of the second excitation electrode 75B. That is, the first layer of the first excitation electrode 75A may have the same thickness as the first layer of the second excitation electrode 75B.

Each resonator of the filter device 70 has the same or substantially the same configuration as the third example embodiment. In the serial arm resonator S1, the layer structure of the first excitation electrode 75A has the same arrangement of materials from the piezoelectric layer 4 side as the layer structure of the second excitation electrode 76A, and the layer structure of the first wiring electrode 77A has the same arrangement of materials from the piezoelectric layer 4 side as the layer structure of the second wiring electrode 78A. In the parallel arm resonator P1, the layer structure of the first excitation electrode 75B has the same arrangement of materials from the piezoelectric layer 4 side as the layer structure of the second excitation electrode 76B, and the layer structure of the first wiring electrode 77B has the same arrangement of materials from the piezoelectric layer 4 side as the layer structure of the second wiring electrode 78B. Thus, in each of the serial arm resonator S1 and the parallel arm resonator P1, the stress applied thereto can be reduced as a whole similarly to the third example embodiment. The same applies to the other resonators.

In each resonator, preferably, the layer structure of the first excitation electrode has the same arrangement of materials and thicknesses from the piezoelectric layer 4 side as the layer structure of the second excitation electrode, and the layer structure of the first wiring electrode has the same arrangement of materials and thicknesses from the piezoelectric layer 4 side as the layer structure of the second wiring electrode. This can further reduce the stress applied to each resonator of the filter device 70.

While example embodiments of the present invention have been described above, it is to be understood that variations and modifications will be apparent to those skilled in the art without departing from the scope and spirit of the present invention. The scope of the present invention, therefore, is to be determined solely by the following claims.

What is claimed is:

1. An acoustic wave device, comprising:
a piezoelectric layer including a first major surface and a second major surface opposing each other;
a first excitation electrode on the first major surface of the piezoelectric layer and a second excitation electrode on the second major surface;
a first wiring electrode coupled to the first excitation electrode and a second wiring electrode coupled to the second excitation electrode; and
an insulating layer on the second major surface of the piezoelectric layer and covering at least a portion of the second excitation electrode and the second wiring electrode;
wherein the first excitation electrode and the second excitation electrode oppose each other with the piezoelectric layer sandwiched therebetween;
a region in the piezoelectric layer sandwiched between the first excitation electrode and the second excitation electrode defines an excitation region;
an acoustic reflector is provided within the insulating layer and overlaps at least a portion of the excitation region in plan view;
neither the first wiring electrode nor the second wiring electrode overlaps the acoustic reflector in plan view; and
a layer structure of the first excitation electrode has a same arrangement of a material from a piezoelectric layer side, as a layer structure of the second excitation electrode, and a layer structure of the first wiring electrode has a same arrangement of a material from the piezoelectric layer side, as a layer structure of the second wiring electrode.

2. The acoustic wave device according to claim 1, wherein the layer structure of the first excitation electrode has a same thickness from the piezoelectric layer side as the layer structure of the second excitation electrode, and the layer structure of the first wiring electrode has a same thickness from the piezoelectric layer side as the layer structure of the second wiring electrode.

3. The acoustic wave device according to claim 1, wherein each of the first wiring electrode and the second wiring electrode includes a plurality of wiring electrode layers, and materials of the plurality of wiring electrode layers are different from the materials of the first excitation electrode and the second excitation electrode.

4. The acoustic wave device according to claim 1, wherein each of the first excitation electrode and the second excitation electrode includes a plurality of electrode layers.

5. The acoustic wave device according to claim 1, further comprising a peripheral structure on at least one of an outer edge of the first excitation electrode and an outer edge of the second excitation electrode.

6. The acoustic wave device according to claim 5, wherein the peripheral structure includes a first peripheral structure on the first excitation electrode and a second peripheral structure on the second excitation electrode; and
shapes of the first peripheral structure and the second peripheral structure are congruent in plan view, an entirety or substantially an entirety of the first peripheral structure overlaps an entirety or substantially an entirety of the second peripheral structure in plan view, and a thickness and a material of the first peripheral structure are the same as a thickness and a material of the second peripheral structure.

7. The acoustic wave device according to claim 1, wherein at least one cross section passing through the piezoelectric layer, the first excitation electrode, the second excitation electrode, the first wiring electrode, and the second wiring electrode includes a portion in which the first excitation electrode and the second excitation electrode are point-symmetric and the first wiring electrode and the second wiring electrode are point-symmetric.

8. The acoustic wave device according to claim 1, wherein, in plan view, a symmetry axis with respect to which the first excitation electrode is line-symmetric, a symmetry axis with respect to which the second excitation electrode is line-symmetric, a symmetry axis with respect to which at least a portion of the first wiring electrode is line-symmetric, and a symmetry axis with respect to which at least a portion of the second wiring electrode is line-symmetric coincide with each other.

9. The acoustic wave device according to claim 1, further comprising:
a first extended electrode on the first major surface of the piezoelectric layer and extending from the first excitation electrode; and
a second extended electrode on the second major surface and extending from the second excitation electrode; wherein
the first wiring electrode is provided on the first extended electrode;
the second wiring electrode is provided on the second extended electrode;
a layer structure of the first extended electrode has a same arrangement of a material as the layer structure of the first excitation electrode; and
a layer structure of the second extended electrode has a same arrangement of a material as the layer structure of the second excitation electrode.

10. The acoustic wave device according to claim 9, wherein
an outer edge of the first wiring electrode is positioned inside an outer edge of the first extended electrode in plan view; and
the acoustic wave device includes at least one of a configuration in which, in at least a portion of the first wiring electrode, a dimension of the first wiring electrode in a first width direction is greater than a maximum dimension of the first excitation electrode in the first width direction and a configuration in which, in at least a portion of the second wiring electrode, a dimension of the second wiring electrode in a second width direction is greater than a maximum dimension of the second excitation electrode in the second width direction, where the first width direction is a direction perpendicular or substantially perpendicular to a direction in which the first wiring electrode extends and the second width direction is a direction perpendicular or substantially perpendicular to a direction in which the second wiring electrode extends.

11. The acoustic wave device according to claim 10, wherein
the acoustic wave device includes at least one of a configuration in which, in every portion of the first wiring electrode, the dimension of the first wiring electrode in the first width direction is greater than the maximum dimension of the first excitation electrode in the first width direction and a configuration in which, in every portion of the second wiring electrode, the dimension of the second wiring electrode in the second width direction is greater than the maximum dimension of the second excitation electrode in the second width direction.

12. The acoustic wave device according to claim 1, further comprising a dielectric film on the first excitation electrode.

13. The acoustic wave device according to claim 12, wherein
the dielectric film is provided on a portion of the first excitation electrode that overlaps the acoustic reflector in plan view;
the insulating layer includes an intermediate portion between the acoustic reflector and the second excitation electrode; and
the dielectric film is made of a same material as the insulating layer and has a same thickness as the intermediate portion.

14. The acoustic wave device according to claim 1, further comprising:
a support substrate; wherein
the piezoelectric layer is indirectly stacked on the support substrate with the insulating layer interposed therebetween.

15. The acoustic wave device according to claim 1, wherein, in plan view, the acoustic reflector faces the first wiring electrode and the second wiring electrode with gaps therebetween.

16. The acoustic wave device according to claim 1, wherein the acoustic reflector is a cavity portion included within the insulating layer.

17. The acoustic wave device according to claim 1, wherein
the acoustic reflector includes an acoustic reflection film provided within the insulating layer;
the acoustic reflection film includes at least one low-acoustic impedance layer having a relatively low acoustic impedance and at least one high-acoustic impedance layer having a relatively high acoustic impedance; and
the at least one low-acoustic impedance layer and the at least one high-acoustic impedance layer are alternately stacked on each other.

18. The acoustic wave device according to claim 1, further comprising:
a support on the first wiring electrode; and
a lid on the support.

19. The acoustic wave device according to claim 1, wherein the piezoelectric layer includes at least one of lithium tantalate, lithium niobate, or aluminum nitride.

20. A filter device, comprising:
a serial arm resonator; and
a parallel arm resonator, wherein
at least one of the serial arm resonator and the parallel arm resonator includes the acoustic wave device according to claim 1.
